(19) United States
(12) Patent Application Publication
(10) Pub. No.: US 2014/0049153 A1
(43) Pub. Date: Feb. 20, 2014

(54) LIGHT-EMITTING-DEVICE PACKAGE AND A PRODUCTION METHOD THEREFOR

(71) Applicants: Chang Bun Yoon, Bucheon-si (KR); Chul Soo Yoon, Suwon-si (KR); Ok Sik Han, Busan-si (KR); Min Jung Park, Hanam-si (KR)

(72) Inventors: Chang Bun Yoon, Bucheon-si (KR); Chul Soo Yoon, Suwon-si (KR); Ok Sik Han, Busan-si (KR); Min Jung Park, Hanam-si (KR)

(73) Assignee: SAMSUNG ELECTRONICS CO., LTD., Suwon-si, Gyeonggi-do (KR)

(21) Appl. No.: 14/114,139

(22) PCT Filed: Apr. 27, 2012
(86) PCT No.: PCT/KR2012/003302

§ 371 Date: Oct. 25, 2013

(30) Foreign Application Priority Data
Apr. 27, 2011 (KR) 10-2011-0039467

(51) Int. Cl. H01L 33/50

(52) U.S. Cl. CPC H01L 33/50
USPC 313/498; 445/23

(57) ABSTRACT

According to one embodiment of the present invention, a light-emitting-device package comprises a wavelength-converting layer which is formed on a light-emitting-device chip, comprises a fluorescent body and crystallized glass, and converts the wavelength of the light generated from the light-emitting-device chip. Consequently, by making the refractive indices of the phosphor and the crystallized glass comprised in the wavelength-converting layer coincide, it is possible to reduce the scattering losses which occur when the refractive indices differ. As a result, it is possible to improve the light-extraction efficiency of the light-emitting-device package. Also, because the to light-emitting-device package uses the wavelength-converting layer comprising the phosphor and the crystallized glass, the processability and reliability are outstanding and it is possible to reduce the processing time when the light-emitting-device package is produced.

### TECHNICAL FIELD

The present invention relates to a light-emitting-device package and a manufacturing method thereof, and more particularly, to a light-emitting-device package and a manufacturing method thereof that reduces scattering loss.

### BACKGROUND ART

A light-emitting-device (or a light emitting diode, LED) may refer to a semi-conductor light-emitting-device that emits light when a current flows. The light-emitting-device has been used extensively in lighting devices, electric display panels, a backlight of a display device, and the like, due to longevity, low power consumption, a prompt response speed, an excellent initial operation property, and the like, and fields to which the light-emitting-device may be applied are expanding to a greater extent.

In recent times, the light-emitting-device is being used as a light source of various colors. With an increasing demand for a high power and high luminance light-emitting-device, such as a white light-emitting-device for lighting, and the like, research into enhancing performance and reliability of a light-emitting-device package is being conducted in earnest.

In order to enhance performance of light-emitting-device products, achieving a light-emitting-device package that efficiently extracts light, has excellent color purity, and has products in a uniform property may be necessary, along with a light-emitting-device having excellent light efficiency.

To obtain a white light-emitting-device using a light-emitting-device, a fluorescent body, hereinafter referred to as a phosphor, may be disposed on a blue or ultraviolet (UV) ray light-emitting-device. The white light-emitting-device may perform color conversion on a portion of light extracted from the UV ray or blue light-emitting-device into a combination of red, green, blue, and yellow phosphors, and mix the color converted portion of light to obtain a white color.

In particular, in a white light-emitting-device package, a short-wavelength light emitted from a light-emitting-device chip passes through a phosphor, and a portion of the short-wavelength light changes to a long-wavelength light, thereby emitting a white light. Further, the phosphor may absorb light energy of the short-wavelength, and function as a wavelength-converting layer that converts the absorbed light energy into red, green, and yellow lights. Elements of determining performance of the white light-emitting-device may include color uniformity in terms of a color quality, and a most importantly, efficiency.

The efficiency may include internal quantum efficiency and light-extraction efficiency. The internal quantum efficiency may refer to a ratio at which an electric charge injected from a light-emitting-device is converted to a photon in an active layer, and the light-extraction efficiency may refer to a ratio at which light emitted from a light-emitting-device chip is emitted externally through a phosphor.

In general, the white light-emitting-device package may perform color conversion through disposing a phosphor layer around the light-emitting-device chip, and use a scheme for extracting light via a sealing resin. In a process in which the UV ray or blue light emitted from the light-emitting-device chip is converted to a white light subsequent to encountering the phosphor layer, the color converted light may be scattered by a phosphor particle.

Accordingly, continuous research is being conducted with regard to reducing scattering loss because the light-extraction efficiency may decrease when light undergoes the scattering loss inside the phosphor layer.

### DISCLOSURE OF INVENTION

### Technical Goals

An aspect of the present invention provides a light-emitting-device package for reducing scattering loss and a manufacturing method thereof.

### Technical Solutions

According to an aspect of the present invention, there is provided a light-emitting-device package, including a package body including a cavity and a lead frame to be disposed inside the cavity, a light-emitting-device chip to be mounted on a bottom surface of the cavity, and wire-bonded to the lead frame, and a wavelength-converting layer to be formed on the light-emitting-device chip, include a fluorescent body, hereinafter referred to as a phosphor, and a crystallized glass, and convert a wavelength of light generated from the light-emitting-device chip.

Refractive indices of the phosphor and the crystallized glass may be identical to one another.

The refractive indices of the phosphor and the crystallized glass may be in a range of 1.5 to 1.9.

A surface of the wavelength-converting layer may be textured.

The wavelength-converting layer may be provided in a form of a plate.

The wavelength-converting layer may be transparent.

A weight ratio of the phosphor to the crystallized glass may be in a range of 6:4 to 1:9.

The phosphor is selected from a group consisting of a yttrium aluminum garnet (YAG) phosphor, a lutetium aluminum garnet (LuAG) phosphor, a silicon aluminia nitride (SiAlON) phosphor, a sulfide phosphor, and a silicate phosphor.

According to an aspect of the present invention, there is provided a method for manufacturing a light-emitting-device package, the method including preparing a package body including a cavity and a lead frame to be disposed inside the cavity, mounting a light-emitting-device chip on a bottom surface of the cavity, and wire-bonding the lead frame and the light-emitting-device chip, and forming, on the light-emitting-device chip, a wavelength-converting layer to include a phosphor and a crystallized glass, and convert a wavelength of light generated from the light-emitting-device chip.

The wavelength-converting layer may include a composite produced by the phosphor and the crystallized glass being sintered at a temperature in a range of 600 degrees Celsius to 900 degrees Celsius.

The refractive indices of the phosphor and the crystallized glass may be in a range of 1.5 to 1.9.

The wavelength converting layer may be provided in a form of a plate.

A surface of the wavelength converting layer may be textured.

A weight ratio of the phosphor to the crystallized glass may be in a range of 6:4 to 1:9.

### Effects of Invention

According to an aspect of the present invention, there is provided a light-emitting-device package that is formed on a light-emitting-device chip including a fluorescent body, hereinafter referred to as a phosphor, and a crystallized glass, and a wavelength-converting layer that converts a wavelength of light generated from the light-emitting-device chip. Accordingly, scattering loss occurring when refractive indices of the phosphor and the crystallized glass included in the wavelength-converting layer differ may decrease through matching the refractive indices of the phosphor and the crystallized glass. Transitively, the light-emitting-device package may enhance light-extraction efficiency.

Also, the light-emitting-device package may be excellent in processability and reliability, and reduce a process time for manufacturing the light-emitting-device package, through use of a wavelength-converting layer including the phosphor and the crystallized glass.

### BRIEF DESCRIPTION OF DRAWINGS

FIG. 1 is a cross-sectional view illustrating a light-emitting-device package according to an embodiment of the present invention.

FIG. 2 is a cross-sectional view illustrating a light-emitting-device package according to another embodiment of the present invention.

FIG. 3 is a diagram illustrating a wavelength-converting layer in a light-emitting-device package according to an embodiment of the present invention.

FIG. 4 is a diagram illustrating transparency of the wavelength-converting layer of FIG. 3.

FIG. 5 is a diagram illustrating a processed photo of the wavelength-converting layer of FIG. 3.

FIG. 6 is a diagram illustrating an x-ray diffraction (XRD) result of the wavelength-converting layer of FIG. 3.

FIG. 7 is a graph illustrating an intensity of light based on a wavelength in a light-emitting-device package according to an embodiment of the present invention.

### BEST MODE FOR CARRYING OUT THE INVENTION

Reference will now be made in detail to embodiments of the present invention, examples of which are illustrated in the accompanying drawings, wherein like reference numerals refer to the like elements throughout. The embodiments are described below in order to explain the present invention by referring to the figures.

In describing a plurality of layers, a plurality of surfaces, or a plurality of chips to be formed “on” or “under” the plurality of layers, the plurality of surfaces, or the plurality of chips, “on” and “under” may include being formed “directly” or “indirectly” by interposing other constituents in between in descriptions of embodiments of the present invention. Also, standards of “on” or “under” of a plurality of constituents may be described based on the accompanying drawings.

A size of the plurality of constituents in the drawings may be exaggerated for ease of description, and may not be construed to intend an actual size to be applied.

Hereinafter, a light-emitting-device package according to an embodiment of the present invention will be discussed with reference to the accompanying drawings.

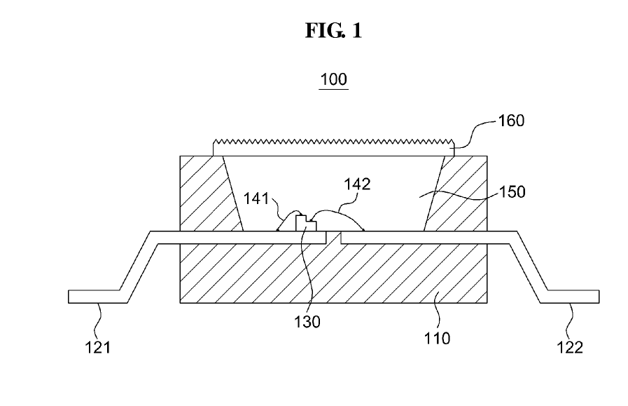

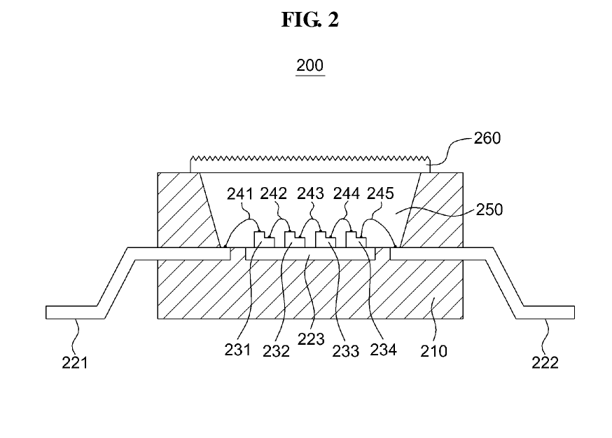

FIG. 1 is a cross-sectional view illustrating a light-emitting-device package 100 according to an embodiment of the present invention. FIG. 2 is a cross-sectional view illustrating a light-emitting-device package 200 according to another embodiment of the present invention.

A light-emitting-device chip 230 is identical to the light-emitting-device package 100 of FIG. 1, aside from a fact that a plurality of light-emitting-device chips 230 is disposed in FIG. 2, and therefore, the light-emitting-device chip 230 will be discussed based on descriptions of FIG. 1.

Reference numerals of a cavity 150, lead frames 121 and 122, a package body 110, a light-emitting-device chip 130, wires 141 and 142, and a wavelength-converting layer 160 in FIG. 1 may correspond to a cavity 250, lead frames 221 and 222, a package body 210, light-emitting-device chips 231, 232, 233, and 234, wires 241, 242, 243, 244, and 245, and a wavelength-converting layer 260 in FIG. 2, respectively.

Referring to FIG. 1, the light-emitting-device package 100 may include the cavity 150, the lead frames 121 and 122, the package body 110, the light-emitting-device chip 130, the wires 141 and 142, and the wavelength-converting layer 160.

The package body 110 may include the cavity 150, a first lead frame 121, and a second lead frame 122. The light-emitting-device chip 130 may be mounted in the cavity 150. In particular, the light-emitting-device chip 130 may be mounted on a bottom surface of the cavity 150. The first lead frame 121 and the second lead frame 122 may be disposed inside the cavity 150, and particularly, on the bottom surface of the cavity 150 to be extended towards an outside of the package body 110.

The light-emitting-device chip 130 may be mounted on the first lead frame 121 disposed on the bottom surface of the cavity 150, and electrically connected to the first lead frame 121 and the second lead frame 122 that are distanced apart from one another through bonding the wires 141 and 142.

Also, a third lead frame 223 may further be provided to mount the plurality of to light-emitting-device chips 231, 232, 233, and 234 inside the cavity 250 of the light-emitting-device package, as shown in FIG. 2.

A relationship between disposition of the lead frames and the light-emitting-device chips, and a structure of connection by the wires may not be construed to be limiting, and may changed in various manners.

The wavelength-converting layer 160 may be formed on the light-emitting-device chip 130. The wavelength-converting layer 160 may include a fluorescent body, hereinafter referred to as a phosphor, and a crystallized glass. The wavelength-converting layer 160 may function to convert a wavelength of light generated from the light-emitting-device chip 130. The wavelength-converting layer 160 may perform an identical function of converting the wavelength of light in an instance in which the plurality of light-emitting-device chips is mounted as shown in FIG. 2, and may be formed in a form of a plate on the plurality of light-emitting-device chips as described in the following.

When the light-emitting-device package generates a white light, the light-emitting-device chip 130 may generate light of an ultraviolet (UV) ray wavelength area, and the wavelength-converting layer 160 may include blue, green, and red phosphors.

Also, when the light-emitting-device package generates a white light, the light-emitting-device chip 130 may generate light of a blue wavelength area, and the wavelength-converting layer 160 may include a yellow phosphor.

A phosphor included in the wavelength-converting layer 160 may be selected from a group consisting of a yttrium aluminum garnet (YAG) phosphor, a lutetium aluminum garnet (LuAG) phosphor, a silicon aluminia nitride (SiAlON) phosphor, a sulfide phosphor, and a silicate phosphor.

The crystallized glass to be included in the wavelength-converting layer 160 may include silicon dioxide (SiO₂), barium oxide (BaO), boron trioxide (B₂O₃), or sodium carbonate (Na₂CO₃). Here, a dielectric constant may be low when the crystallized glass to be included in the wavelength-converting layer 160 contains SiO_{2, BaO, and B}₂O₃, and the dielectric constant may be high when the crystallized glass to be included in the wavelength-converting layer 160 contains SiO₂, BaO, and Na₂CO₃. Also, a refractive index of the crystallized glass may be adjusted based on a BaO content, and when the BaO content is high, the refractive index of the crystallized glass may increase.

Refractive indices of the phosphor and the crystallized glass included in the wavelength-converting layer 160 may be identical to one another. Here, the refractive indices of the phosphor and the crystallized glass may be in a range of about 1.5 to about 1.9, and in particular, may have a value of 1.7. Scattering loss occurring due to differing refractive indices may be reduced because the refractive indices of the phosphor and the crystallized glass to be included in the wavelength-converting layer 160 are identical to one another.

In particular, the scattering loss occurring due to differing refractive indices of the phosphor and ceramic resins included in the wavelength-converting layer 160 functioning to convert light generated from the light-emitting-device chip 130 to light of a desired wavelength may be reduced through use of a crystallized glass having a refractive index identical to the refractive index of the phosphor in the wavelength-converting layer 160.

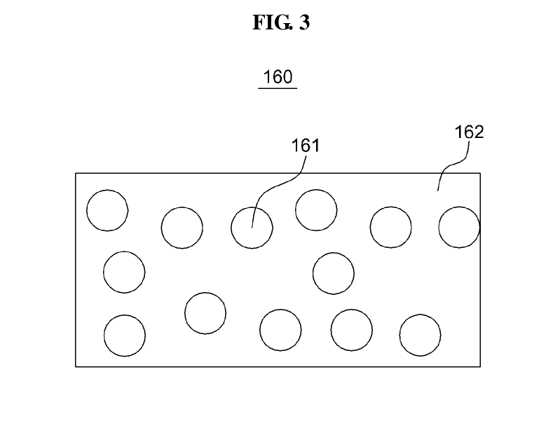

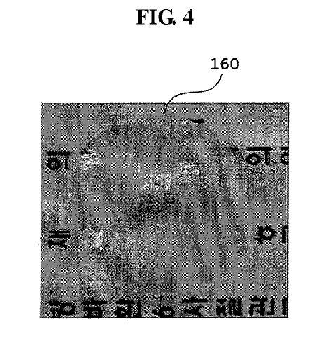

As shown in FIG. 3, the wavelength-converting layer 160 in the light-emitting-device package may be provided in a form of a plate in which the phosphor is inserted into the crystallized glass. Also, the wavelength-converting layer 160 may be transparent as shown in FIG. 4.

A weight ratio of the phosphor to the crystallized glass may be in a range of about 6:4 to about 1:9, and in particular, may be in an optimal range of about 4:6 to about 1:9. By way of example, the weight ratio of the phosphor to the crystallized glass may be 3:7.

When a phosphor content to be included in the wavelength-converting layer 160 is high, light-extraction efficiency of the light-emitting-device package may increase because a thickness of the wavelength-converting layer 160 may be diminished. Transitively, a particle size of a glass powder may be in a range of about 2 to about 3 micrometers (μm) in order to increase the phosphor content.

Also, a surface of the wavelength-converting layer 160 may be textured, and thereby the light-extraction efficiency of the light-emitting-device package may be enhanced.

The wavelength-converting layer 160 of the light-emitting-device package may reduce scattering loss through use of the crystallized glass having the refractive index in a range of about 1.5 to about 1.9 identical to the refractive index of the phosphor, and enhance light-extraction efficiency through texturing the surface of the wavelength-converting layer 160. Further, to enhance the light-extraction efficiency, the wavelength-converting layer 160 may function through the form being changed a form other than the plate, for example a dome, and the like.

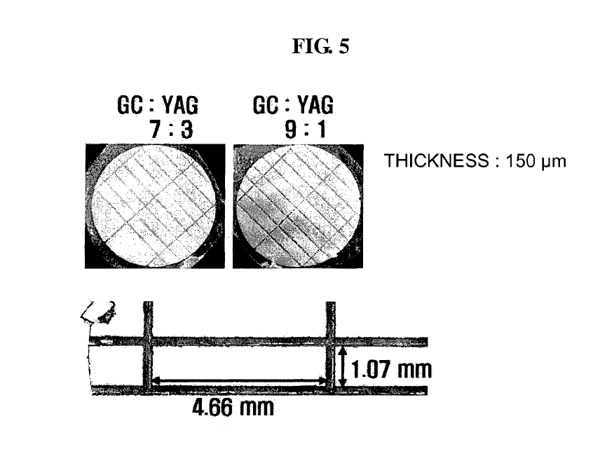

Additionally, through use of the wavelength-converting layer 160 including the crystallized glass, excellent processability as shown in FIG. 5 may be achieved. In particular, as shown in FIG. 5 illustrating processed photos of the wavelength-converting layer, a precise process may be made possible because a line width tolerance of the wavelength-converting layer including the crystallized glass and the phosphor at a ratio of 7:3 and 9:1 is processable in an approximate range of ±10 μm.

In one example, a general form of glass, due to an amorphous nature thereof, may be easily damaged and thus, reliability and longevity may decrease when a relatively small amount of external energy is applied. However, the crystallized glass may have a small coefficient of thermal expansion, and endure radical changes in temperature. Also, processability and reliability of the crystallized glass may be enhanced due to a great amount of thermal shock resistance because a compressive force and a tensile force may be formed on a surface and an inside of the crystallized glass.

Accordingly, excellent processability and reliability may be achieved to be used for lighting and an electronic device through the crystallized glass being included in the wavelength-converting layer 160 in the light-emitting-device package.

Moreover, a process time for manufacturing the light-emitting-device package may be reduced because the wavelength-converting layer 160 may be produced separately from the light-emitting-device chip to be attached.

Hereinafter, a method for manufacturing a light-emitting-device package will be described in detail. As described in the foregoing, the light-emitting-device package 100 of FIG. 1 will be used as a reference.

The method for manufacturing the light-emitting-device package may include preparing a package body including a cavity and a lead frame to be disposed inside the cavity, mounting a light-emitting-device chip on a bottom surface of the cavity, and wire-bonding the lead frame and the light-emitting-device chip, and forming, on the light-emitting-device chip, a wavelength-converting layer to include a phosphor and a crystallized glass, and convert a wavelength of light generated from the light-emitting-device chip.

The package body is prepared to mount the light-emitting-device chip. More particularly, a first lead frame and a second lead frame may be formed on the bottom surface of the package body, and the light-emitting-device chip may be mounted on the first lead frame. Here, when a plurality of light-emitting-device chips is mounted as shown in FIG. 2, a third lead frame may further be provided.

The first lead frame and the second lead frame may be wire-bonded to the light-emitting-device chip, subsequent to the first lead frame being mounted on the light-emitting-device chip. In particular, the light-emitting-device chip may include two electrodes of which a light-emitting surface has differing polarities, and the two electrodes may be wire-bonded, respectively, to be electrically connected to the first lead frame and the second lead frame.

The light-emitting-device chip and the lead frame may be connected to a wire, and a wavelength-converting layer may be formed on the light-emitting-device chip. The wavelength-converting layer may include a composite produced by a phosphor and a crystallized glass being sintered at a temperature in a range of about 600 degrees Celsius to about 900 degrees Celsius.

Here, refractive indices of the phosphor and the crystallized glass may be in a range of about 1.5 to 1.9, and in particular, may have a value of 1.7. Also, the wavelength-converting layer may be in a form of a plate, and a surface of the wavelength-converting layer may be textured.

As described in the foregoing, when the wavelength-converting layer applies heat to a phosphor and a glass consisting of SiO₂, BaO, B₂O₃, or Na₂CO₃ at a temperature in a range of about 600 degrees Celsius to about 900 degrees Celsius and freeze the phosphor and the glass, the glass may be phase transformed to a crystallized glass.

In particular, when heat is applied to a glass to reach a temperature greater than a melting point to be frozen to reach less than a predetermined temperature, the glass may be phase transformed to a crystallized glass. As such, when the glass is phase transformed to the crystallized glass, a strong crystallized peak is verified to occur to be to crystallized, through measuring an x-ray diffraction (XRD) of a complex including the phosphor and the crystallized glass.

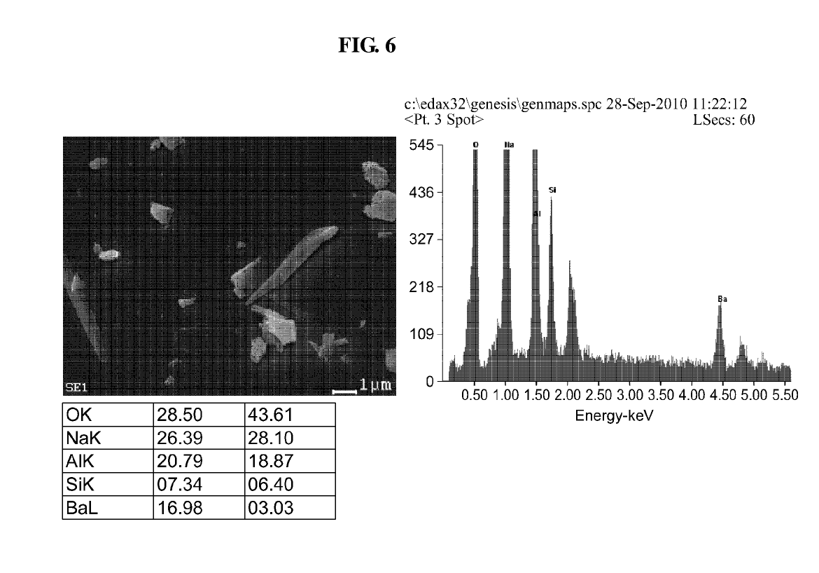

FIG. 6 is a diagram illustrating an XRD result of a wavelength-converting layer including a phosphor and a crystallized glass according to an embodiment of the present invention. Referring to FIG. 6, when a glass is phase transformed to a crystallized glass, a crystallized peak of a plurality of elements, for example, oxygen (O), sodium (Na), aluminum (Al), silicon (Si), and barium (Ba), of the crystallized glass, may be verified to be present. Transitively, the wavelength-converting layer may be verified to include the phosphor and the crystallized glass through the glass being phase transformed to the crystallized glass at a temperature in a range of about 600 degrees Celsius and to about 900 degrees Celsius.

An intensity of light based on a wavelength may vary according to a weight ratio of the phosphor to the crystallized glass to be included in the wavelength-converting layer, and values of “x” and “y” in Commission International de l'Eclairage (CIE) chromaticity coordinates may change. The weight ratio of the phosphor to the crystallized glass to be included in the wavelength-converting layer may be in a range of about 6:4 to about 1:9. By way of example, the weight ratio of the phosphor to the crystallized glass may be in an optimal range of about 4:6 to about 1:9, and in particular, may be 3:7.

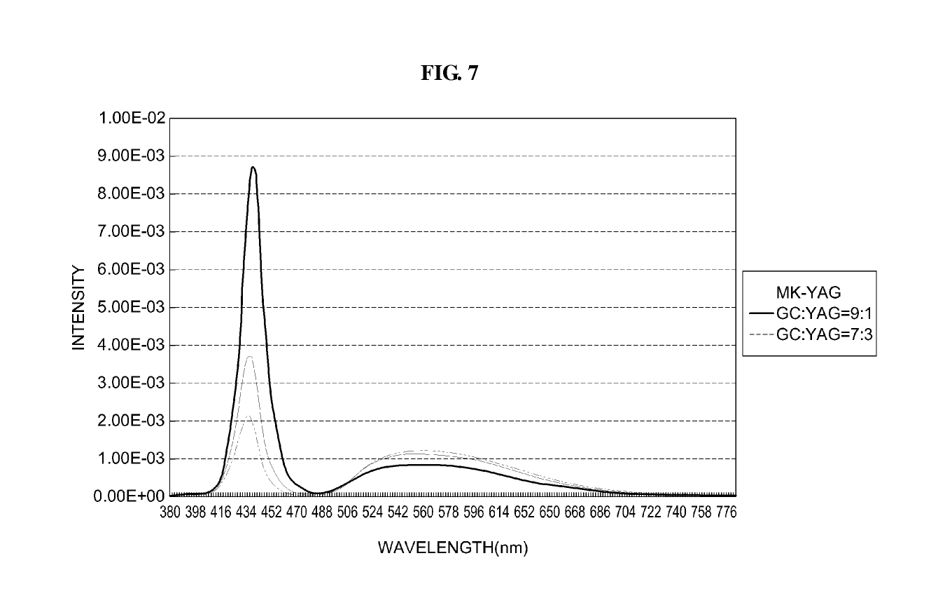

FIG. 7 is a graph illustrating an intensity of light based on a wavelength in a light-emitting-device package according to an embodiment of the present invention.

In FIG. 7, YAG may not include a crystallized glass, and may refer to a light-emitting-device package to which a YAG phosphor powder is applied, and a ratio of CG:YAG may include a crystallized glass and a YAG phosphor as a weight ratio of the crystallized glass to the YAG phosphor, and refer to a light-emitting-device package provided in a form of a plate.

Referring to FIG. 7, at 450 nanometers (nm) of a wavelength, a light-emitting-device package including a complex of which GC:YAG is 9:1 has a highest intensity of light, a light-emitting-device package of YAG has a medium intensity of light, and a light-emitting-device package including a complex of which GC:YAG is 7:3 has a lowest intensity of light. The light-emitting-device package including the complex of which GC:YAG is 7:3 has a higher conversion ratio of a blue light emitted from a light-emitting-device chip than the light-emitting-device package of YAG

Table 1 represents a lumen (lm) value of the light-emitting-device package of FIG. 7, values of “x” and “y” of CIE chromaticity coordinates, a light-emitting wavelength (Wp) of a light-emitting-device chip.

TABLE 1

| | | | |
|---|---|---|---|
| lm | x | y | Wp |

YAG

| | | | | |
|---|---|---|---|---|
| Mean value | 65.74 | 0.32 | 0.30 | 434.99 |
| Maximum value | 68.03 | 0.32 | 0.31 | 436.75 |
| Minimum value | 63.08 | 0.30 | 0.28 | 432.91 |

GC:YAG = 7:3

| | | | | |
|---|---|---|---|---|
| Mean value | 68.89 | 0.36 | 0.37 | 434.28 |
| Maximum value | 72.38 | 0.37 | 0.40 | 434.83 |
| Minimum value | 64.70 | 0.35 | 0.36 | 433.53 |

GC:YAG = 9:1

| | | | | |
|---|---|---|---|---|
| Mean value | 51.35 | 0.24 | 0.15 | 437.45 |
| Maximum value | 52.63 | 0.24 | 0.16 | 437.98 |
| Minimum value | 49.05 | 0.23 | 0.14 | 437.09 |

Table 2 represents a percentage of the lm value in the light-emitting-device package including the complex of which GC:YAG is 7:3 and of which GC:YAG is 9:1, based on a mean lm value of YAG.

TABLE 2

| | lm | lm (%) |
|---|---|---|
| YAG | 65.74 | 100 |
| GC:YAG = 7:3 | 68.89 | 104.8 |
| GC:YAG = 9:1 | 51.35 | 78.1 |

Referring to FIG. 7, Tables 1 and 2, the light-emitting-device package including the complex of which GC:YAG is 9:1 has a lowest mean lm value, the light-emitting-device package of YAG has a medium mean lm value, and the light-emitting-device package including the complex of which GC:YAG is 7:3 has a highest mean lm value. Transitively, the light-emitting-device package including the complex of which GC:YAG is 7:3 has a higher conversion ratio of a blue light emitted from the light-emitting-device chip and a higher lm value than the light-emitting-device package of YAG.

Also, the light-emitting-device package of YAG, the light-emitting-device to package including the complex of which GC:YAG is 7:3, and the light-emitting-device package including the complex of which GC:YAG is 9:1 may all represent a white light. However, the light-emitting-device package including the complex of which GC:YAG is 7:3 may represent a warm white light, and the light-emitting-device package including the complex of which GC:YAG is 9:1 may represent a cool white light.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. A light-emitting-device package, comprising:
a package body including a cavity and a lead frame to be disposed inside the cavity;
a light-emitting-device chip to be mounted on a bottom surface of the cavity, and wire-bonded to the lead frame; and
a wavelength-converting layer to be formed on the light-emitting-device chip, include a fluorescent body (a phosphor), and a crystallized glass, and convert a wavelength of light generated from the light-emitting-device chip.

2. The light-emitting-device package of claim 1, wherein refractive indices of the phosphor and the crystallized glass are identical to one another.

3. The light-emitting-device package of claim 2, wherein the refractive indices of the phosphor and the crystallized glass are in a range of 1.5 to 1.9.

4. The light-emitting-device package of claim 1, wherein a surface of the wavelength-converting layer is textured.

5. The light-emitting-device package of claim 1, wherein the wavelength-converting layer is provided in a form of a plate.

6. The light-emitting-device package of claim 1, wherein the wavelength-converting layer is transparent.

7. The light-emitting-device package of claim 1, wherein a weight ratio of the phosphor to the crystallized glass is in a range of 6:4 to 1:9.

8. The light-emitting-device package of claim 1, wherein the phosphor is selected from a group consisting of a yttrium aluminum garnet (YAG) phosphor, a lutetium aluminum garnet (LuAG) phosphor, a silicon aluminia nitride (SiAlON) phosphor, a sulfide phosphor, and a silicate phosphor.

9. A method for manufacturing a light-emitting-device package, the method comprising:
preparing a package body including a cavity and a lead frame to be disposed inside the cavity;
mounting a light-emitting-device chip on a bottom surface of the cavity, and wire-bonding the lead frame and the light-emitting-device chip; and
forming, on the light-emitting-device chip, a wavelength-converting layer to include a phosphor and a crystallized glass, and convert a wavelength of light generated from the light-emitting-device chip.

10. The method of claim 9, wherein the wavelength-converting layer comprises a composite produced by the phosphor and the crystallized glass being sintered at a temperature in an approximate range of 600 degrees Celsius to 900 degrees Celsius.

11. The method of claim 9, wherein the refractive indices of the phosphor and the crystallized glass are in a range of 1.5 to 1.9.

12. The method of claim 9, wherein the wavelength converting layer is provided in a form of a plate.

13. The method of claim 9, wherein a surface of the wavelength converting layer is textured.

14. The method of claim 9, wherein a weight ratio of the phosphor to the crystallized glass is in a range of 6:4 to 1:9.
